(19) United States
(12) Patent Application Publication
(10) Pub. No.: US 2009/0217976 A1
(43) Pub. Date: Sep. 3, 2009

(54) Solar cell with integrated thermally conductive and electrically insulating substrate

(75) Inventors: Robert Cart, Berkeley, CA (US); John A. Herb, Palo Alto, CA (US); Kevin Richard Fine, Redwood City, CA (US); Jesse Dennis Wolfe, Bullhead City, AZ (US)

Correspondence Address: VAN PELT, YI & JAMES LLP, 10050 N. FOOTHILL BLVD #200, CUPERTINO, CA, 95014, US

(73) Assignee: GREEN VOLTS, INC.

(21) Appl. No.: 12/322,840

(22) Filed: Feb. 6, 2009

Related U.S. Application Data
(60) Provisional application No. 61/063,971, filed on Feb. 6, 2008.
(60) Provisional application No. 61/072,009, filed on Mar. 26, 2008.
(60) Provisional application No. 61/070,698, filed on Mar. 24, 2008.
(60) Provisional application No. 61/123,499, filed on Apr. 9, 2008.

(51) Int. Cl. H01L 31/02; H01L 21/50; H01L 21/302

(52) U.S. Cl. 136/256; 438/64; 438/68; 257/E21.499; 257/E21.214; 257/E31.11

(57) ABSTRACT

A solar cell package and processes for creating a solar cell package are disclosed. The solar cell includes an electrically insulating and thermally conductive first layer, an electrically conductive second layer attached to the first layer, and a solar cell attached to the second layer. The first layer surface and a solar cell surface have substantially the same surface area.

### CROSS REFERENCE TO OTHER APPLICATIONS

This application claims priority to U.S. Provisional Patent Application No. 61/063,971 (Attorney Docket No. GREEP009+) entitled SOLAR CELL WITH INTEGRATED HEAT SPREADER filed Feb. 6, 2008, U.S. Provisional Patent Application No. 61/072,009 (Attorney Docket No. GREEP008+) entitled ENCAPSULANT FOR PHOTOVOLTAIC DEVICE filed Mar. 26, 2008, U.S. Provisional Patent Application No. 61/070,698 (Attorney Docket No. GREEP010+) entitled REDUCING COST AND IMPROVING PERFORMANCE OF A HIGH PERFORMANCE SINGLE CRYSTAL SOLAR CELL filed Mar. 24, 2008, and U.S. Provisional Patent Application No. 61/123,499 (Attorney Docket No. GREEP0012+) entitled A WAFER BONDING METHOD FOR REDUCING COST AND IMPROVING PERFORMANCE OF A HIGH PERFORMANCE SINGLE CRYSTAL SOLAR CELL filed Apr. 9, 2008 which are incorporated herein by reference for all purposes.

### BACKGROUND OF THE INVENTION

Solar power systems include concentrating and non-concentrating systems. In non-concentrating solar power systems, the solar cell receives unconcentrated sunlight. An example of a non-concentrating solar power system is a flat panel of photovoltaic (PV) cells. In concentrating solar power systems, the solar cell receives sunlight that has been concentrated by an optical concentrator and directed at the receiving solar cell. An example of a concentrating solar power system is a parabolic collector in which a solar cell is located at the focal point of the concentrating collector. High concentration PV cells perform better and are more reliable when operated at lower temperature ranges. However, the concentration of solar radiation generates large amounts of heat in the cells in excess of that energy converted into electricity. The heat of concentration can damage or destroy the expensive cells. Even at lower temperatures, heat from concentration reduces the efficiency of the output from the cell. Improvements in heat removal in solar power systems are desirable.

### BRIEF DESCRIPTION OF THE DRAWINGS

Various embodiments of the invention are disclosed in the following detailed description and the accompanying drawings.

FIG. 1A is a diagram illustrating a top view of a solar cell package.

FIG. 1B is a diagram illustrating a side view of a solar cell package.

FIG. 2A is a diagram illustrating a side view of an example solar cell.

FIG. 2B is a diagram illustrating top views of example solar cells.

FIG. 3 is a diagram illustrating perspective, top, and side views of an embodiment of a solar cell package in which three edges of the solar cell are mutually aligned with corresponding edges of a substrate.

FIG. 4 is a diagram illustrating perspective, top, and side views of an embodiment of a solar cell package with an underhanging perimeter ledge.

FIG. 5A is a diagram illustrating a perspective view of the bottom of an embodiment of a perimeter contact structure.

FIG. 5B is a diagram illustrating a bottom view of an embodiment of a negative perimeter contact structure.

FIG. 5C is a diagram illustrating a bottom view of an embodiment of a negative perimeter contact structure.

FIG. 6A is a diagram illustrating a side view of an embodiment of a solar cell package with an overhanging perimeter ledge.

FIG. 6B is a diagram illustrating top views of various embodiments of a solar cell package with an underhanging ledge.

FIG. 6C is a diagram illustrating views of various embodiments of a solar cell package with a ledge that is not attached to a substrate.

FIG. 6D is a diagram illustrating an embodiment of a solar cell package with a ledge that is not attached to a substrate.

FIG. 7 is a flow chart illustrating an embodiment of a process for creating a solar cell package at a singulated level.

FIG. 8 is a flow chart illustrating an embodiment of a process for creating a solar cell package at a wafer level.

FIG. 9 is a flow chart illustrating an embodiment of a process for creating a composite wafer comprising a solar cell layer bonded to a substrate layer.

FIG. 10 is a diagram illustrating an example of a process for creating individual solar cell packages from a composite wafer.

FIG. 11 is a flow chart illustrating an embodiment of a process for singulating a solar cell package.

FIG. 12 is a flow chart illustrating an embodiment of a process for creating a composite wafer comprising a solar cell layer bonded to a substrate layer.

FIG. 13 is a diagram illustrating an example of a process for creating a composite wafer comprising a solar cell layer bonded to a substrate layer corresponding to process 1200.

FIG. 14 is a flow chart illustrating an embodiment of a process for creating a pre-growth composite wafer through deposition.

FIG. 15 is a flow chart illustrating an embodiment of a process for creating a pre-growth composite wafer through bonding.

FIG. 16 is a flow chart illustrating an embodiment of a process for creating a pre-growth composite wafer from a semiconductor boule.

FIG. 17 is a diagram illustrating an example of a process for creating a pre-growth composite wafer from a semiconductor boule.

FIG. 18 is a diagram illustrating an encapsulant for a photovoltaic device.

FIG. 19A is a diagram illustrating a patterned GaAs substrate ready for epitaxial growth.

FIG. 19B is a diagram illustrating a schematic comparison between a thin solar cell and a conventional three layer solar cell.

FIG. 19C is a diagram illustrating a schematic diagram of a ceramic substrate attached to a semiconductor wafer.

FIG. 19D is a diagram illustrating a schematic of an individual solar cell after release.

FIG. 19E is a diagram illustrating a solar cell on a ceramic substrate with wire bonds.

FIG. 20A is a diagram illustrating a schematic diagram of adhesion with a crystal.

FIG. 20B is a diagram illustrating a schematic diagram of etched adhesion.

FIG. 20C is a diagram illustrating a schematic diagram of subsequent epitaxial growth.

### DETAILED DESCRIPTION

The invention can be implemented in numerous ways, including as a process; an apparatus; a system; or a composition of matter. In this specification, these implementations, or any other form that the invention may take, may be referred to as techniques. In general, the order of the steps of disclosed processes may be altered within the scope of the invention.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Improving heat removal from solar cell packages using an integrated heat spreader is disclosed. In some embodiments, heat is spread by reducing thermal resistance of a solar cell package by reducing materials within a solar cell. In some embodiments, the package substrate material is reduced by substantially aligning the package substrate's length and width edges with the length and width edges of the attached solar cell. In some embodiments, the solar cell substrate layer is reduced by reducing its depth (thickness). Reduction of material reduces solar cell package cost, reduces thermal resistance, and increases the efficiency of the solar cell.

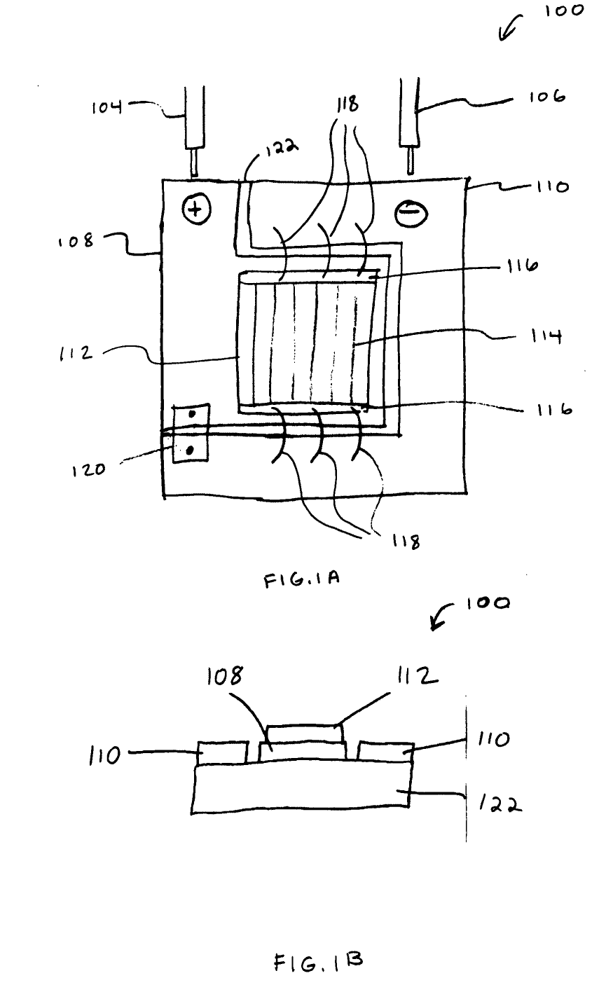

FIG. 1A is a diagram illustrating a top view of a solar cell package. Solar cell package 100 is shown to include wires 104 and 106, positive trace 108, negative trace 110, solar cell 112, wire bonds 118, substrate 122, and bypass diode 120. Solar cell 112 is a solar cell having electrically conductive bus bars 116 and electrically conductive grid 114. Solar energy hits the top surface of solar cell 112, which creates electricity. Bus bars 116 are the negative terminal and the bottom of solar cell 112 is the positive terminal. Wire bonds 118 attach bus bars 116 to negative trace 110. Negative trace 110 and positive trace 108 are typically copper. The bottom of solar cell 112 is attached to positive trace 108 via an electrically conductive material. Wire 104 and wire 106 will attach to positive trace 108 and negative trace 110, respectively. Bypass diode 120 connects positive trace 108 and negative trace 110 as shown. The bottom of traces 108 and 110 are attached to substrate 122, which is better shown in a side view.

FIG. 1B is a diagram illustrating a side view of a solar cell package. Solar cell package 100 is shown to include solar cell 112, positive trace 108, negative trace 110, and substrate 122. The bottom of traces 108 and 110 are attached to substrate 122. Substrate 122 is a ceramic substrate that is electrically insulating and thermally conductive. As such, substrate 122 functions to spread heat from solar cell 112 without shorting positive trace 108 to negative trace 110. In addition, substrate 122 functions as a structural support for the solar cell package.

When sunlight hits the top of solar cell 112, electricity may be generated. In addition, the solar energy that is not converted to electricity is converted into heat, and needs to be removed. Substrate 122 functions to conduct the generated heat away from solar cell 112. Ceramic substrate 122 is relatively large compared to the size of solar cell 112. The ceramic substrate is typically in contact with the entire bottom surface of traces 108 and 110 in order to maximize heat spreading to conduct heat away from solar cell 112. The ceramic substrate also needs to be thick since it provides structural support. In addition, ceramic substrate 122 may be large in order to increase the number of features provided by the ceramic. Because high quality ceramic material that is a good electrical insulator and thermal conductor is costly, typically, a lower quality ceramic material is used for substrate 122. A lower quality ceramic may be less electrically insulating and less thermally conductive.

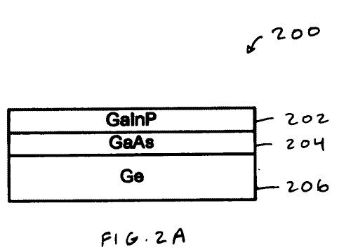

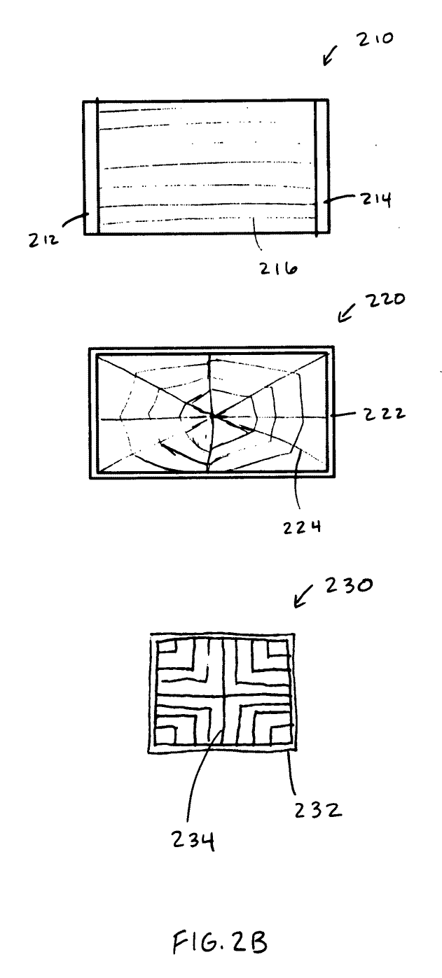

FIG. 2A is a diagram illustrating a side view of an example solar cell. In this example, a triple junction solar cell is shown. In various embodiments, any other type of solar cell, including any multiple layer junction solar cells, concentrating or non-concentrating solar cells, may be used. Solar cell 200 is shown to include a layer of Gallium Indium Phosphide (GaInP) 202 on top of a layer of Gallium Arsenide (GaAs) 204, which is on top of a layer of Germanium (Ge). In various embodiments, other solar cells based on other materials may be used. Within each layer, there may be two or more sublayers. For example, there may be 60 sublayers. For example, not shown in the figure are the tunnel junction and grading layers that may be part of a multiple junction solar cell.

In some embodiments, the top or front of the solar cell provides the negative electrical contact and the bottom or back of the solar cell provides the positive electrical contact.

FIG. 2B is a diagram illustrating top views of example solar cells.

In some embodiments, solar cell 210 is a top view of solar cell 200. Solar cell 210 is shown to include bus bars 212 and 214 and grid 216. In this embodiment, grid 216 comprises a plurality of parallel electrically conductive lines connected between bus bars 212 and 214. Such paths provide an electrical path from all areas of the semiconductor or solar cell top surface.

In some embodiments, solar cell 220 is a top view of solar cell 200. Solar cell 220 is shown to include perimeter bus bar 222, which is located along the perimeter of the top of the solar cell. In this embodiment, grid 224 is a radial pattern of electrically conductive lines connected to perimeter bus bar 222.

In some embodiments, solar cell 230 is a top view of solar cell 200. Solar cell 230 is shown to include perimeter bus bar 232, which is located along the perimeter of the top of the solar cell. In this embodiment, grid 234 is another example pattern of electrically conductive lines connected to perimeter bus bar 222.

In various embodiments, other configurations of bus bars and grids may be used on the solar cell.

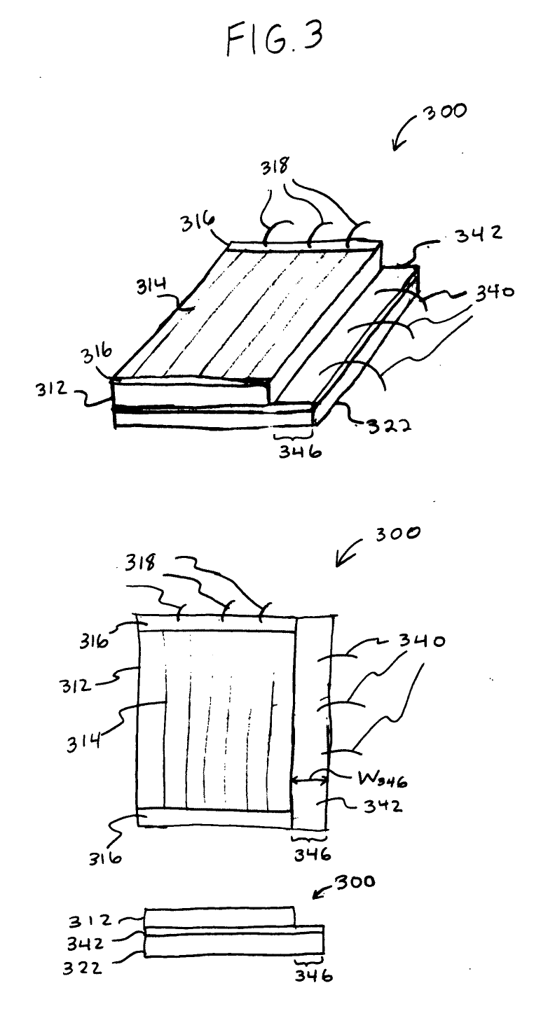

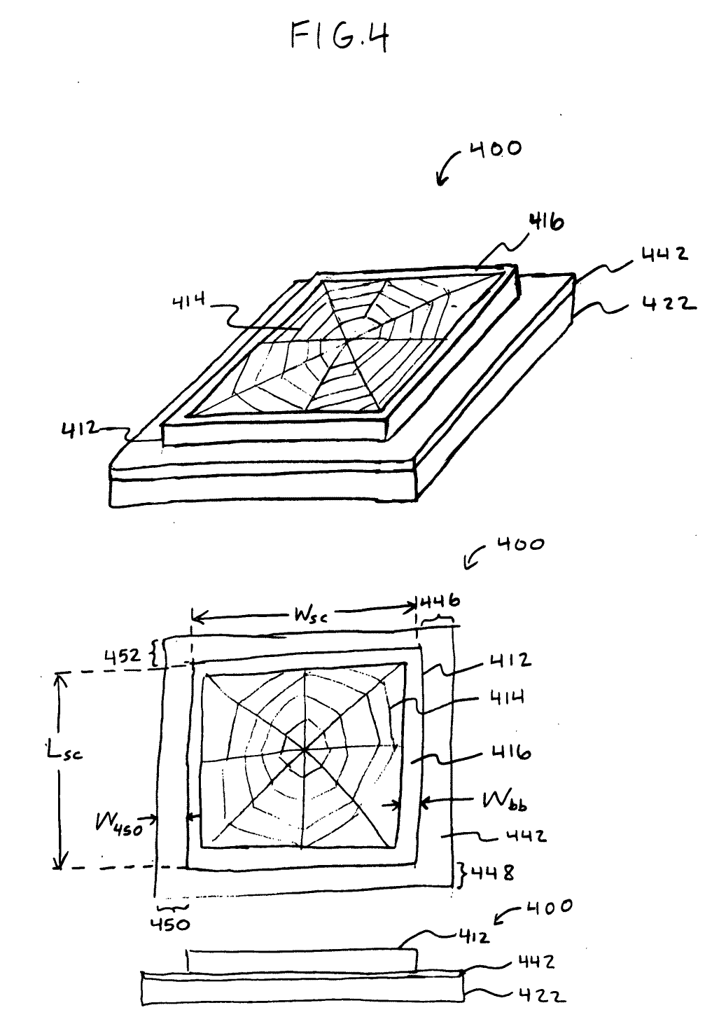

FIG. 3 is a diagram illustrating perspective, top, and side views of an embodiment of a solar cell package in which three edges of the solar cell are mutually aligned with corresponding edges of a substrate.

Solar cell package 300 is shown to include solar cell 312, electrically conductive layer 342, substrate 322, negative wire bonds 318, and positive wire bonds 340. In this example, solar cell 312 is a solar cell with parallel bus bars, such as solar cell 210. Solar cell 312 includes bus bars 316 and parallel grid 314. Negative wire bonds 318 are attached to bus bars 316, the negative terminal. The positive terminal of solar cell 312 is at the bottom of solar cell 312, which is attached via electrically conductive layer 342 to substrate 322. Positive wire bonds connect to electrically conductive layer 342, the positive terminal. Substrate 322 is an electrically insulating, thermally conductive material, such as a ceramic, Aluminum Nitride (AlN), diamond, Alumina (Al₂O₃), Si₃N₄, SiO2, semiconductors, such as semi-insulating silicon, or other dielectrics.

Electrically conductive layer 342 may be a metal, for example. As used herein, an electrically conductive layer may include gold, silver, copper, aluminum, alloys, solder, or other metals, and an electrically conductive layer may include one or more sublayers. In some embodiments, electrically conductive layer 342 functions both to provide an external electrical connection to the positive terminal and as an adhesive, bonding solar cell 312 to substrate 322.

In this example, three edges of solar cell 312 are mutually aligned with three edges of substrate 322. The three edges that are mutually aligned are: (1) the rear edge, running along the width of each structure (rear width edge); (2) the left edge, running along the length of each structure (left length edge); and (3) the front edge, running along the width of each structure (front width edge). (In the top view, length is the vertical direction and width is the horizontal direction.) The fourth edge is the right edge, running along the length of each structure (right length edge). The fourth edge of substrate 322 extends beyond the fourth edge of solar cell 312 to create ledge 346. Ledge 346 provides an external electrical connection to the negative terminal of solar cell 312 via electrically conductive layer 342.

In various embodiments, the edges may or may not be mutually aligned. In some embodiments, one or more edges of substrate 322 extends beyond the corresponding edge(s) of solar cell 312 to create 1-4 (underhanging) ledges. In some embodiments, one or more edges of solar cell 312 extends beyond the corresponding edge(s) of substrate 322 to create 1-4 (overhanging) ledges. In some embodiments, a ledge is not rectangular and therefore not uniform in width. For example, a ledge may be triangular in shape. Some of these embodiments are more fully discussed below.

As used herein, the ledge width refers to the distance by which a ledge extends beyond the edge of the solar cell. In the case of an underhanging ledge as in solar cell package 300, the ledge width refers to the distance by which the ledge extends beyond the edge of the solar cell in the direction away from the solar cell. For example, the ledge width of ledge 346 is W₃₄₆. In the case of an overhanging ledge, the ledge width refers to the distance by which the ledge extends beyond the edge of the solar cell in the direction towards the solar cell.

The four edges of solar cell 312 and the four edges of substrate 322 are substantially aligned in length and width. In some embodiments, substantially aligned edges means that a ledge between a first edge and a second edge is approximately a few millimeters in ledge width, or less. For example, W₃₄₆ may be 2 millimeters or less. If all four edges of solar cell 312 are substantially aligned with all four edges of substrate 322, then solar cell 312 would be only slightly larger or slightly smaller in length and width than substrate 322. In some embodiments, the ledge width is sized to fit the positive electrical contact. In some embodiments, the ledge width is approximately the minimum size needed to fit the positive electrical contact.

In addition, a surface of substrate 322 and a surface of solar cell 312 have substantially the same surface area. In some embodiments, a first surface and a second surface having substantially the same surface area means that the surface area of the first surface does not exceed twice the surface area of the second surface and vice versa (i.e., the surface area of the second surface does not exceed twice the surface area of the first surface).

In some embodiments, a first surface and a second surface having substantially the same surface area means that the surface area of the first surface does not exceed the surface area of the second surface plus a margin of 2 mm around the perimeter of the second surface, and vice versa (i.e., the surface area of the second surface does not exceed the surface area of the first surface plus a margin of 2 mm around the perimeter of the first surface).

In this example, the surface of substrate 322 that is in contact with layer 342 and the surface of solar cell 312 that is in contact with the layer 342 have substantially the same surface area. In the example shown, the surface of substrate 322 that is in contact with electrically conductive layer 342 is the top surface of substrate 322. The surface of solar cell 312 that is in contact with electrically conductive layer 342 is the bottom surface of solar cell 312.

When sunlight hits the top of solar cell 312, electricity may be generated. In addition, the solar energy that is not converted to electricity is converted into heat, and needs to be removed to reduce the cell temperature. Substrate 322 functions to conduct the generated heat away from solar cell 312. The top surface of substrate 322 is only slightly larger in surface area than the bottom surface of solar cell 112, providing room for electrical contact. Because less material is used for substrate 322 than for substrate 122, a high quality ceramic material that is a good electrical insulator and thermal conductor may be used for substrate 322. A higher quality ceramic is more electrically insulating and/or more thermally conductive and/or better matches the coefficient of thermal expansion of the cell.

As depicted herein, for clarity of explanation, the various views of solar cell packages do not necessarily show every layer or every element in the solar cell package. For example, even though a top view may show a bus bar and grid, the side view may not show the bus bar and grid. Layers such as an antireflective (AR) coating, and/or internal junction layers are not shown. Some layers may include multiple sublayers that are not shown.

FIG. 4 is a diagram illustrating perspective, top, and side views of an embodiment of a solar cell package with an underhanging perimeter ledge. In this embodiment, one or all edges of the solar cell are not mutually aligned with any edges of the substrate.

Solar cell package 400 is shown to include solar cell 412, electrically conductive layer 442, and substrate 422. In this example, solar cell 412 is a solar cell with a perimeter bus bar, such as solar cell 222. Solar cell 412 includes perimeter bus bar 416 and grid 414.

The positive terminal of solar cell 412 is at the bottom of solar cell 412, which is attached via electrically conductive layer 442 to substrate 422. Substrate 422 is an electrically insulating, thermally conductive material, such as a ceramic, Aluminum Nitride (AlN), diamond, Alumina (Al2O3), Si3N4, SiO2, semiconductors, such as semi-insulating silicon, or other dielectrics. Electrically conductive layer 442 may be gold, silver, copper, aluminum, alloys, solder, or other metals. In some embodiments, electrically conductive layer 442 functions both to provide an external electrical connection to an interconnecting terminal and as an adhesive, bonding solar cell 412 to substrate 422.

In this example, none of the edges of solar cell 412 are mutually aligned with any of the edges of substrate 422. Each edge of substrate 422 extends beyond the corresponding edge of solar cell 412 to create a perimeter ledge, or ledge that extends around the perimeter of solar cell 412. As shown in the top view of solar cell package 400, the perimeter ledge extends beyond each edge of solar cell 412. The perimeter ledge comprises four ledges, one on each edge of solar cell 412—right ledge 446 (along the right length edges), front ledge 448 (along the front width edges), left ledge 450 (along the left length edges), and rear ledge 452 (along the rear width edges). The perimeter ledge has four ledge widths, each corresponding to one of the four ledges. For example, the ledge width of ledge 450 is W₄₅₀. In this example, the four ledges 446, 448, 450, and 452 (perimeter ledge) of solar cell package 400 have the same (perimeter) ledge width, Wₚₗ=W₄₅₀. In other words, the perimeter ledge width is uniform. In other embodiments, two or more of the four ledge widths are the same. Any combination of ledge widths is possible in various embodiments. The perimeter ledge provides an external electrical connection to the negative terminal of solar cell 412 via electrically conductive layer 442. The perimeter ledge in this example is an underhanging perimeter ledge.

The edges of solar cell 412 and substrate 422 are substantially aligned in length and width—each of the ledges 446, 448, 450, and 452 between solar cell 412 and substrate 422 is less than a few microns in ledge width. For example, W₄₅₀=2 mm. In addition, the top surface of substrate 422 and the bottom surface of solar cell 412 have substantially the same surface area.

In this example, the width of solar cell 412 is W_{sc}. The length of solar cell 412 is L_{sc}. The width of perimeter bus bar is W_{bb} and is the same on each of the four sides in this example.

In some embodiments, negative wire bonds are attached to bus bar 416, the negative terminal, and positive wire bonds are attached to electrically conductive layer 442 (on the perimeter ledge), the positive terminal. In various embodiments, besides wires, a variety of other bonding options may be used, such as ribbon bonding (i.e., larger flat wires), a leadframe interconnect (e.g., a separate piece of metal that runs the length of the bus and is welded down), attaching another metalized substrate (e.g., attaching a metal to the substrate using welding, solder, or glue), etc. The mechanism for the bonding attachment itself may be solder, welding, adhesives, bonding (e.g., molecular bonding), etc. In some embodiments, a positive perimeter contact structure and a negative perimeter contact structure are placed on solar cell package 400 to provide positive and negative connections to external wires.

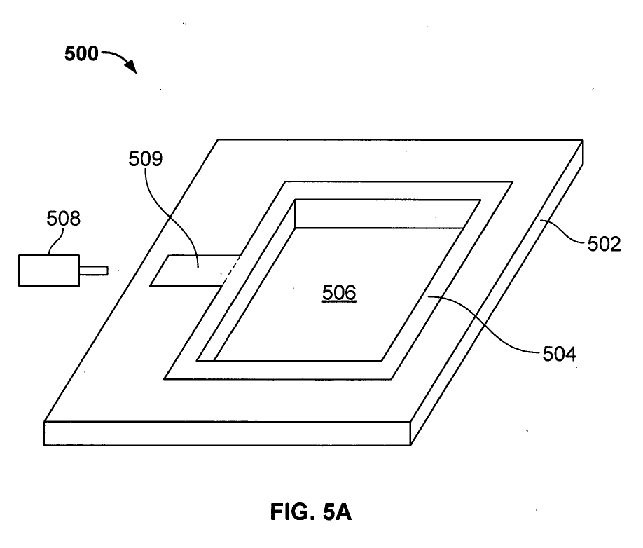

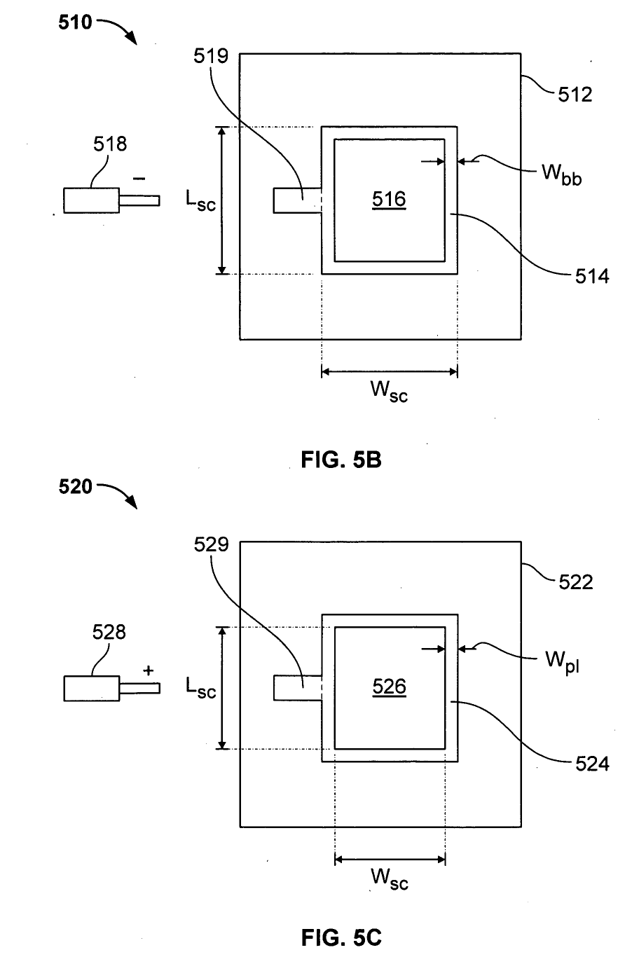

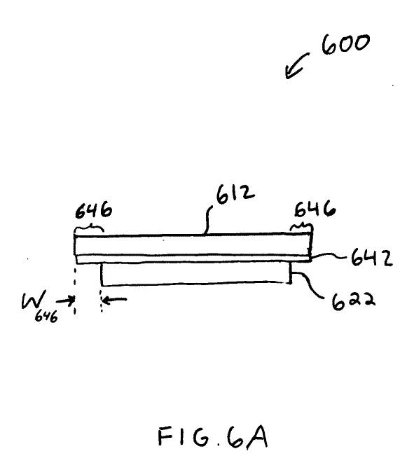

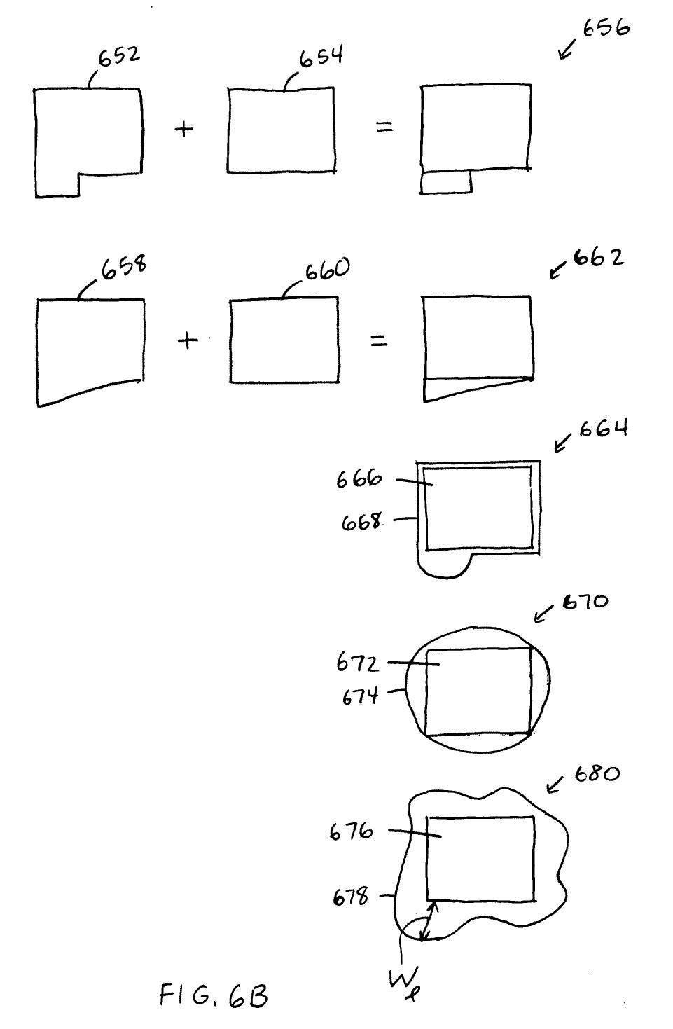

FIG. 5A is a diagram illustrating a perspective view of the bottom of an embodiment of a perimeter contact structure. Perimeter contact structure 500 is shown to include an electrically insulated board 502. For example, board 502 may be made of Flame Retardant-4 (FR-4) or polyimide materials, such as Kapton. At the center of perimeter contact structure 500 is cutout region 506, a rectangular hole cut through board 502. Perimeter contact 504 is on the surface of board 502 and is adjacent to cutout region 506 as shown. Perimeter contact 504 is electrically conductive. For example, perimeter contact 504 may be copper or silver soldered to board 502. Wire 508 will touch perimeter contact 504 at the portion 509 of the perimeter contact 504 that extends towards the outside edge of board 502.

Perimeter contact structure 500 may be used in conjunction with solar cell package 400 as a negative perimeter contact or a positive perimeter contact, depending on the structure of the solar cell, and/or dimensions of cutout region 506.

FIG. 5B is a diagram illustrating a bottom view of an embodiment of a negative perimeter contact structure. In this example, perimeter contact structure 510 is an example of perimeter contact structure 500, with electrically insulated board 512, cutout region 516, and negative perimeter contact 514 adjacent to and extending around the perimeter of cutout region 516. The width of perimeter contact 514 is W_{sc}. The length of perimeter contact 514 is L_{sc}. The width of perimeter contact 514 is W_{bb}. In this example, these dimensions (excluding portion 519) match the dimensions of perimeter bus bar 416 in solar cell package 400. Thus, perimeter contact structure 510 may be placed on top of solar cell package 400 such that perimeter contact 514 contacts perimeter bus bar 416, the negative contact of solar cell package 400. (Note that a bottom view is shown, and so perimeter contact structure 510 is flipped and then placed on top of solar cell package 400.) Portion 519 is a portion of the perimeter contact 514 that extends towards the outside edge of board 512. When perimeter contact structure 520 is placed on top of solar cell package 400, portion 519 is not in contact with perimeter bus bar 416 (i.e., portion 519 extends beyond the edge of solar cell 412) and so provides external access to the negative contact via wire 518.

In this example, the shape and dimensions of perimeter contact 514 (excluding portion 519) match the shape and dimensions of perimeter bus bar 416 to provide electrical contact. In various embodiments, the shape and/or dimensions of perimeter contact 514 (excluding portion 519) do not exactly match the dimensions of perimeter bus bar 416. For example, in some embodiments, perimeter contact 514 does not extend all the way around the perimeter, and only extends a portion of the way around the perimeter.

FIG. 5C is a diagram illustrating a bottom view of an embodiment of a negative perimeter contact structure. In this example, perimeter contact structure 520 is an example of perimeter contact structure 500, with electrically insulated board 522, cutout region 526, and positive perimeter contact 524 adjacent to and extending around the perimeter of cutout region 526.

In this example, the width of cutout region 526 is W_{sc}. The length of cutout region 526 is L_{sc}. The width of perimeter contact 524 is Wₚₗ. Perimeter contact 524 is uniform and has the same width on each side. Therefore, the dimensions of the cutout region match the dimensions of the outer edge of solar cell 412 in solar cell package 400. In addition, the dimensions of perimeter contact 524 (excluding portion 529) match the dimensions of the perimeter ledge of solar cell package 400.

Thus, perimeter contact structure 520 may be placed on top of solar cell package 400 (solar cell 412 fitting through cutout region 526) such that perimeter contact 524 contacts electrically conductive layer 442 on the perimeter ledge, the positive contact of solar cell package 400. (Note that a bottom view is shown, and so perimeter contact structure 520 is flipped and then placed on top of solar cell package 400.) Portion 529 is a portion of the perimeter contact 524 that extends towards the outside edge of board 522. When perimeter contact structure 520 is placed on top of solar cell package 400, portion 529 is not in contact with the perimeter ledge of solar cell package 400 (i.e., portion 529 extends beyond the perimeter ledge) and so provides external access to the negative electrical contact via wire 518.

In this example, the shape and dimensions of perimeter contact 524 (excluding portion 529) are matched to the dimensions of the perimeter ledge of solar cell package 400. In various embodiments, the shape and/or dimensions of perimeter contact 524 (excluding portion 529) do not exactly match the dimensions of the perimeter ledge of solar cell package 400. For example, in some embodiments, perimeter contact 524 does not extend all the way around the perimeter, and only extends a portion of the way around the perimeter.

In some embodiments, first structure 520 is placed on top of solar cell structure 400, and then structure 510 is placed on top of structure 520, thus providing external positive and negative perimeter contacts.

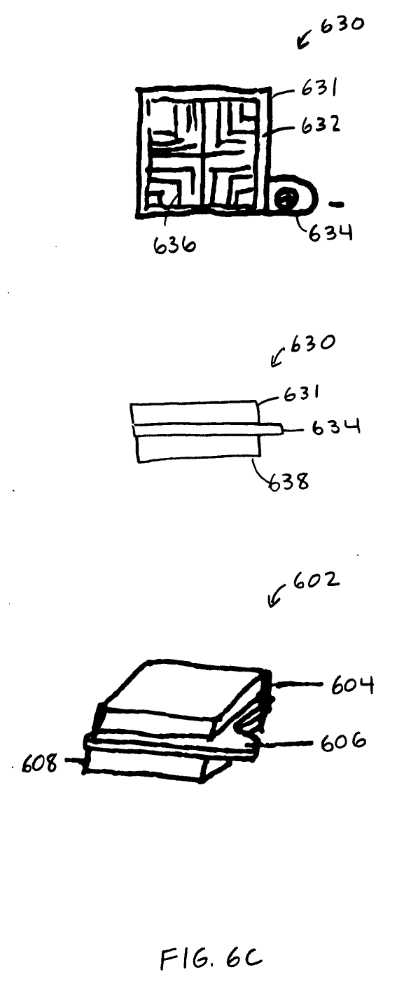

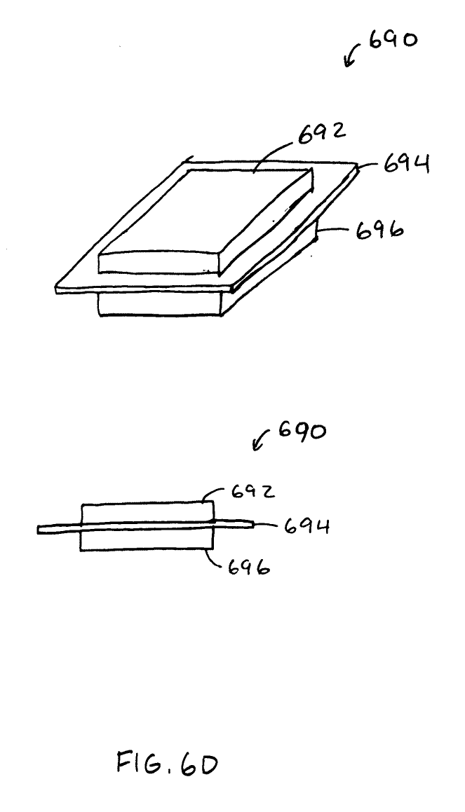

FIG. 6A is a diagram illustrating a side view of an embodiment of a solar cell package with an overhanging perimeter ledge. In this embodiment, no edges of the solar cell are mutually aligned with any edges of a substrate.

Solar cell package 600 is shown to include solar cell 612, electrically conductive layer 642, and substrate 622. An overhanging perimeter ledge 646 extends around the perimeter of substrate 622. In this example, perimeter ledge 646 has a uniform ledge width of W₆₄₆.

In this example, solar cell package 600 is similar to solar cell package 400 except that solar cell 612 is slightly larger than substrate 622. However, the edges of solar cell 612 and substrate 622 are still substantially aligned in length and width because ledge width W₆₄₆<2 mm. In addition, the top surface of substrate 622 and the bottom surface of solar cell 612 have substantially the same surface area in this example.

FIG. 6B is a diagram illustrating top views of various embodiments of a solar cell package with an underhanging ledge.

Solar cell package 656 includes metal coated substrate 652 and solar cell 654. Substrate 652 has a notch in it so that when solar cell 654 is attached to the stop of substrate 652, the notch extends beyond the corresponding edge of solar cell 654 to provide an electrical contact. In this embodiment, three edges of solar cell 654 are mutually aligned with three edges of a substrate. The fourth edge of solar cell 654 is partially mutually aligned with substrate 652. The notch is a ledge that does not extend along the full width of solar cell 654. The ledge width is less than 2 mm. Therefore, the edges of solar cell 654 and the edges of substrate 652 are substantially aligned. In addition, the top surface of substrate 652 and the bottom surface of solar cell 654 have substantially the same surface area in this example.

Solar cell package 662 includes metal coated substrate 658 and solar cell 660. Substrate 658 has an angled edge so that when solar cell 660 is attached to the stop of substrate 658, the angled edge (i.e., a triangular ledge) extends beyond the corresponding edge of solar cell 660 to provide an electrical contact. In this embodiment, three edges of solar cell 654 are mutually aligned with three edges of a substrate. The fourth edge of solar cell 654 forms a triangular ledge that has a nonuniform ledge width (i.e., the ledge width linearly decreases from left to right). The triangular ledge has a maximum ledge width that is less than 2 mm. Therefore, the edges of solar cell 660 and the edges of substrate 658 are substantially aligned. In addition, the top surface of substrate 658 and the bottom surface of solar cell 660 have substantially the same surface area in this example.

Solar cell package 664 includes metal coated substrate 668 and solar cell 666. Substrate 668 has a rounded tab in it so that when solar cell 666 is attached to the stop of substrate 668, the tab extends beyond the corresponding edge of solar cell 666 to provide an electrical contact. In some embodiments, in addition to the tab, there is a perimeter ledge around the perimeter as shown. In other embodiments, there is no perimeter ledge.

The tab is a ledge that does not extend along the full width of solar cell 666. The ledge width is less than 2 mm. In addition, the perimeter ledge width is less than 2 mm on all sides. Therefore, the edges of solar cell 666 and the edges of substrate 668 are substantially aligned. In addition, the top surface of substrate 668 and the bottom surface of solar cell 666 have substantially the same surface area in this example.

Solar cell package 670 includes metal coated substrate 674 and solar cell 672. Substrate 674 is circular and sized so that when solar cell 672 is attached to the stop of substrate 674, portions of the circle extend beyond the edges of solar cell 672 to provide an electrical contact. In some embodiments, substrate 674 circumscribes solar cell 672. If solar cell 672 is a square, the portions of the circle that extends beyond the edges of solar cell 672 are four wedges or wedge-shaped ledges. The portions of the circle that extend beyond the edges of solar cell 672 form one or more ledges with nonuniform ledge widths. The maximum ledge width is less than 2 mm. Therefore, the edges of solar cell 672 and the edges of substrate 674 are substantially aligned. In addition, the top surface of substrate 674 and the bottom surface of solar cell 672 have substantially the same surface area in this example.

Solar cell package 680 includes metal coated substrate 678 and solar cell 676. Substrate 678 is a free form shape so that when solar cell 676 is attached to the stop of substrate 678, portions of the free form shape extend beyond the edges of solar cell 676 to provide an electrical contact. The portions of the free form shape that extend beyond the edges of solar cell 676 form one or more ledges with nonuniform ledge widths. The maximum ledge width (W₁) is less than 2 mm. Therefore, the edges of solar cell 676 and the edges of substrate 678 are substantially aligned. In addition, the top surface of substrate 678 and the bottom surface of solar cell 676 have substantially the same surface area in this example.

As shown by the above examples, in various embodiments, a variety of shapes and sizes may be used for the substrate.

FIG. 6C is a diagram illustrating views of various embodiments of a solar cell package with a ledge that is not attached to a substrate.

Solar cell package 630 is shown in top view and side view. Solar cell package 630 is shown to include solar cell 631, perimeter bus bar 632, grid 636, leadframe 694, and substrate 638. In this example, grid 636 is similar to grid 230. In various embodiments, various solar cells with various types of bus bars and grids may be used. In this example, solar cell 631 and substrate 636 are approximately the same length and width. Leadframe 694 is an electrically conductive structure that is between solar cell 631 and substrate 638. In some embodiments, leadframe 694 is an electrically conductive layer between solar cell 631 and substrate 638. Leadframe 694 has a tab that extends beyond the edge of solar cell 631 and the edge of substrate 638 to allow electrical contact. In some embodiments, the leadframe is tinned in advance and/or soldered to the cell and the substrate.

Solar cell package 602 is shown in perspective view. Solar cell package 602 is shown to include solar cell 604, leadframe 694, and substrate 608. In this example, leadframe 694 has both an edge (in the front) and a tab (on the right) that extends beyond the edge of solar cell 604 and the edge of substrate 608 to allow electrical contact. In some embodiments, the leadframe is tinned in advance and/or soldered to the cell and the substrate.

FIG. 6D is a diagram illustrating an embodiment of a solar cell package with a ledge that is not attached to a substrate. Solar cell package 690 is shown in perspective view and side view. Solar cell package 690 is shown to include solar cell 692, leadframe 694, and substrate 696. In various embodiments, various solar cells with various types of bus bars and grids may be used. In this example, solar cell 692 and substrate 636 are approximately the same length and width. Leadframe 694 is an electrically conductive structure that is between solar cell 692 and substrate 696. In some embodiments, leadframe 694 is an electrically conductive layer between solar cell 692 and substrate 696. Leadframe 694 has a perimeter ledge that extends beyond the edge of solar cell 692 and the edge of substrate 696 to allow electrical contact. The top/bottom surface of leadframe 694 is larger in surface area than the bottom surface of solar cell 692 and the top surface of substrate 696. In some embodiments, the leadframe is tinned in advance and/or soldered to the cell and the substrate.

As demonstrated by the above examples, in some embodiments, a leadframe may be the electrically conductive layer. The leadframe may extend beyond the edges of both the solar cell and the substrate.

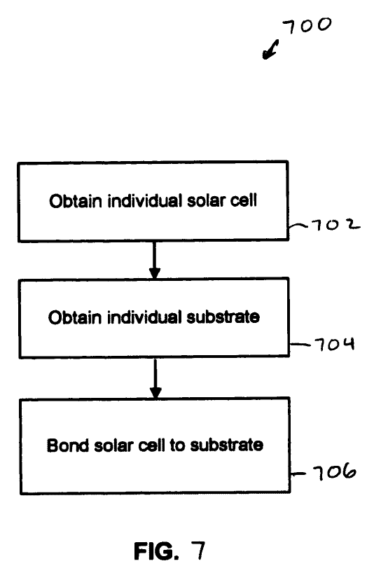

FIG. 7 is a flow chart illustrating an embodiment of a process for creating a solar cell package at a singulated level. For example, process 700 may be used to create solar cell package 300, 400, or 600. At 702, an individual solar cell is obtained. In some embodiments, the individual solar cell already has a bus bar, grid, and AR coating. For example, solar cell 312 is obtained. In some embodiments, the individual solar cell has a metalized back (i.e., a layer of metal on the bottom of the solar cell). At 704, an individual substrate is obtained. For example, substrate 322 is obtained. In some embodiments, the individual substrate has a metalized back. At 706, the solar cell is bonded to the substrate. For example, solar cell 312 is bonded to substrate 322 via electrically conductive material 342. In some embodiments, the bonding is via solder, adhesive, or epoxy, such as a silver filled epoxy.

FIG. 8 is a flow chart illustrating an embodiment of a process for creating a solar cell package at a wafer level. For example, process 800 may be used to create solar cell package 300, 400, or 600. At 802, a composite wafer comprising a solar cell layer bonded to a substrate layer is created. At 804, individual solar cell packages are singulated from the composite wafer. Details of the above steps are more fully described below.

Attaching the solar cell layer to the substrate layer while it is still in wafer form takes advantage of batch processing of semiconductor fabrication to reduce fabrication steps and minimize handling of individual parts. In doing this, the cost of the solar cell package is lowered.

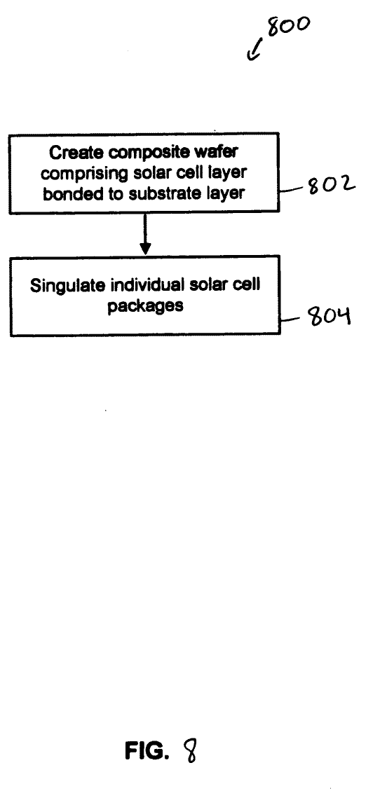

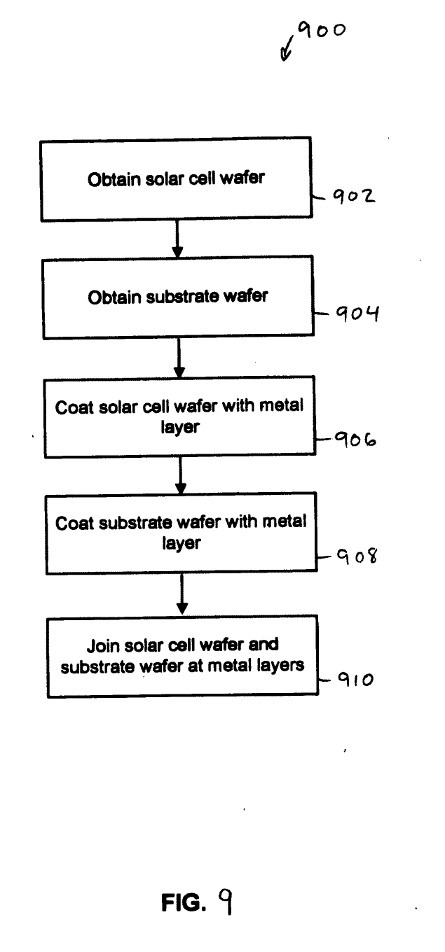

FIG. 9 is a flow chart illustrating an embodiment of a process for creating a composite wafer comprising a solar cell layer bonded to a substrate layer. For example, process 900 may be used to perform 802.

At 902, a solar cell wafer is obtained. At 904, a substrate wafer is obtained. At 906, the solar cell wafer is coated with a metal layer. At 908, the substrate wafer is coated with a metal layer. Although metal may be described as a material used in some embodiments, metal or any other electrically conductive material may be used in various embodiments. Examples of metal that may be used include silver, silver alloys, gold, gold alloys, copper, solder and/or aluminum. At 910, the solar cell wafer and substrate wafer are joined at the metal layers. For example, a wafer bonding process of appropriate temperature and pressure may be used to join the wafers and create the composite wafer. For example, one wafer may be positively charged and the other wafer may be negatively charged. The two charged wafers can be put together and the appropriate amount of heat and pressure applied in order to join the metal layers and thereby bond the two wafers. In some embodiments, wafer bonding includes a molecular bond. Wafer bonding in many instances is a stronger and more thermally conductive bond in comparison to solder, weld, or adhesive bonds. Wafer bonding is more fully discussed below.

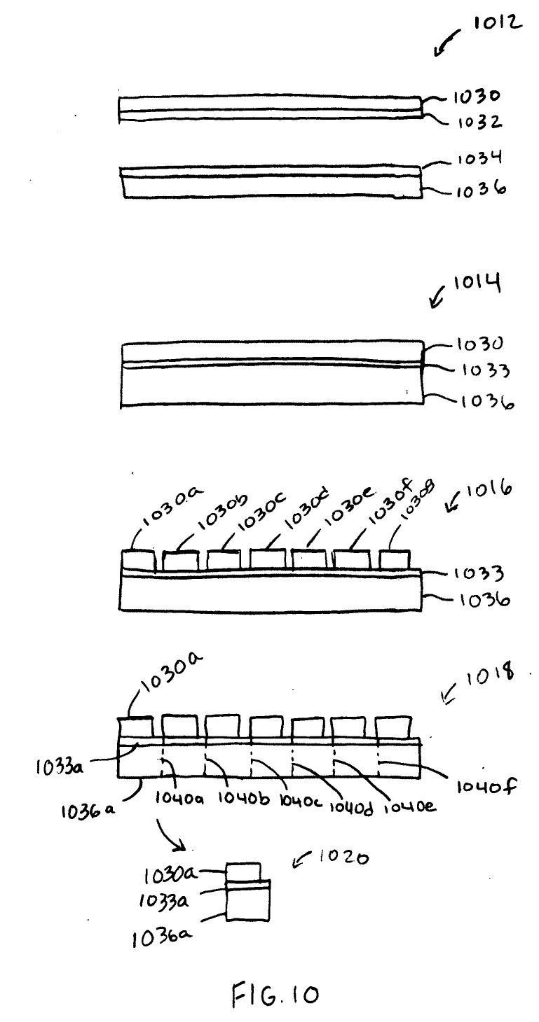

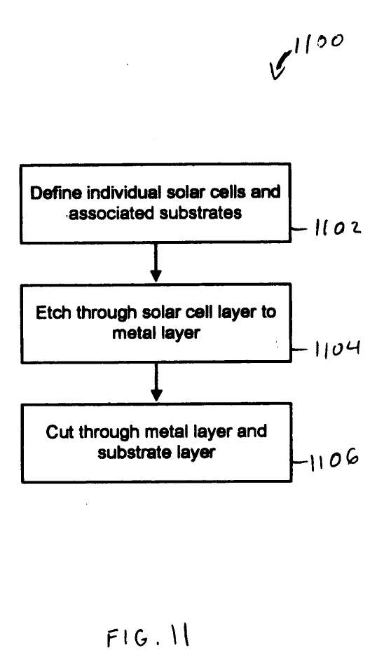

FIG. 10 is a diagram illustrating an example of a process for creating individual solar cell packages from a composite wafer. Diagrams 1012 and 1014 show an example of process 900. Diagram 1012 shows a side view of the structures after 908. Diagram 1012 includes solar cell wafer 1030 coated with metal layer 1032 and substrate wafer 1036 coated with metal layer 1034. Diagram 1014 shows a side view of the composite wafer after 910. Diagram 1014 includes solar cell wafer 1030 bonded to substrate wafer 1036 via metal layer 1033. Metal layer 1033 was formed from joining metal layers 1032 and 1034.

Diagrams 1016, 1018, and 1020 show an example of 804, singulating solar cell packages, which is discussed more fully below.

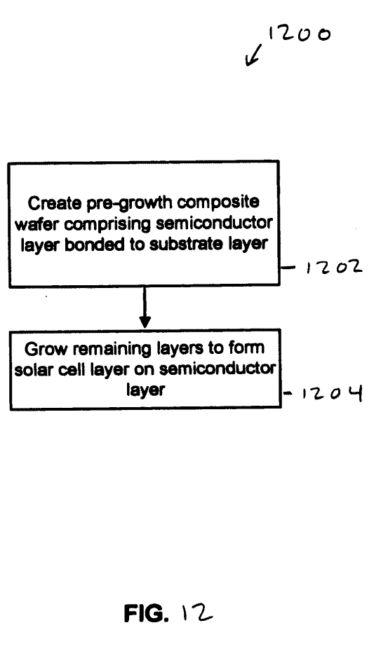

FIG. 11 is a flow chart illustrating an embodiment of a process for singulating a solar cell package. For example, this process may be used to perform 804. At 1102, individual solar cells and associated substrates are defined on the composite wafer. At 1104, etching through the solar cell layer to the metal layer is performed. For example, photolithography is used to perform 1102 and 1104. An appropriate etchant is used so that the etchant does not etch through the metal layer. At 1106, the wafer is cut through the metal layer and substrate layer. The cutting is at appropriate locations to obtain the desired ledge(s) for the solar cell package. For example, the cut can be performed by laser or a wire saw.

Returning to FIG. 10, diagrams 1016, 1018, and 1020 show an example of process 900 for the case in which the solar cell package 300 is created. Diagram 1016 shows a side view of the structure after 1104. Diagram 1016 includes individual solar cells 1030a-1030g, metal layer 1033, and substrate layer 1036. In some embodiments, the gaps between individual solar cells 1030a-1030g were created using photolithography. Diagram 1018 shows a side view of 1106. Diagram 1018 shows cut lines 1040a-1040f. Diagram 1020 shows a side view of one of the solar cell packages after 1106. Diagram 1020 shows a side view of individual solar cell 1030a bonded to individual substrate 1036a via metal layer 1033a, or solar cell package 300.

In this example, cut lines 1040a-1040f are aligned with the left edges of the individual solar cells to produce solar cell package 300, which has one ledge. The cut lines may be in other locations to produce other solar cell packages. For example, to produce solar cell package 400, which has a uniform perimeter ledge, the cut lines would be halfway between the edges of the individual solar cells.

Also, diagrams 1016 and 1018 are side views. A top view of diagram 1016 would show troughs etched out in a grid pattern to create the individual solar cells. A top view of diagram 1018 would show cut lines cut in a grid pattern to cut out the individual solar cell packages.

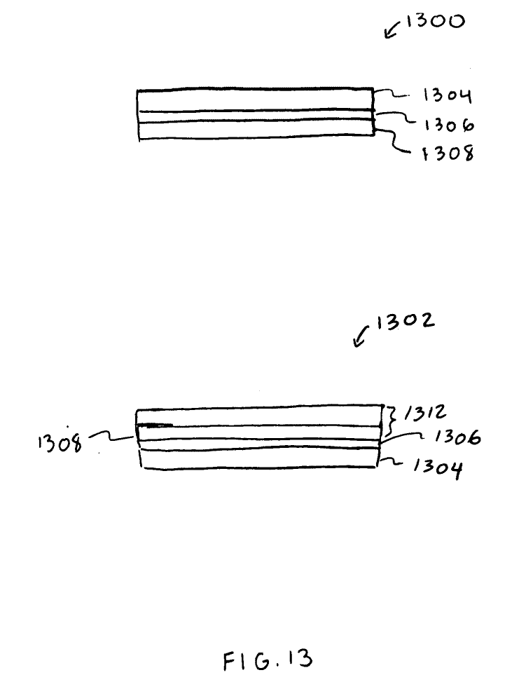

FIG. 12 is a flow chart illustrating an embodiment of a process for creating a composite wafer comprising a solar cell layer bonded to a substrate layer. For example, process 1200 may be used to perform 802 and is an alternative to process 900. At 1202, a pre-growth composite wafer comprising a semiconductor layer bonded to a substrate layer (via a metal layer) is created. As used herein, “pre-growth” refers to a composite wafer prior to growing all the layers to form a solar cell layer on the composite wafer. The semiconductor may be Ge, GaAs, Si, or a III-V semiconductor in various embodiments. The semiconductor is the solar cell substrate layer or the first layer of the solar cell, upon which the remaining layers of the solar cell will be grown. Various embodiments of performing 1202 are described more fully below.

At 1204, the remaining layers to form a solar cell layer are grown on the semiconductor layer. For example a chemical vapor deposition (CVD) process may be used to grow the remaining layers. For example, if the solar cell comprises the layers shown in solar cell 200 (FIG. 2B), then a GaAs layer is grown on the semiconductor (Ge) layer, and then a GaInP layer is grown on the GaAs layer. In some embodiments, the solar cell layer does not include bus bars, a grid, or an AR coating at this point. In some embodiments, the semiconductor surface is polished or otherwise prepared for epitaxial growth prior to 1204.

In various embodiments, the solar cell layer may be grown right side up (standard stack) or upside down (inverted stack). For example, in the case of the inverted stack, instead of Ge, the semiconductor layer may be GaInP. GaAs may be grown on the GaInP layer, and then Ge may be grown on the GaAs layer. In various embodiments, there are other layers in between the various junction layers described. In addition, epitaxial growth could be lattice matched or lattice mismatched.

FIG. 13 is a diagram illustrating an example of a process for creating a composite wafer comprising a solar cell layer bonded to a substrate layer corresponding to process 1200. Diagram 1300 shows a side view of the pre-growth composite wafer after 1202. Diagram 1300 includes substrate layer 1304, metal layer 1306, and semiconductor layer 1308. In some embodiments, metal layer 1306 is an adhesion promoting interlayer that provides a back side electrical contact. Substrate layer 1304 provides support for the structure so that the use of semiconductor material for semiconductor layer 1308 can be minimized. For example, semiconductor layer 1308 may be on the order of 160 microns or less thick. Semiconductor layer 1308 can be thin because substrate layer 1304 provides structural support for the structure. Without substrate layer 1304, semiconductor layer 1308 is subject to breakage, especially with fragile semiconductor materials, such as Ge and GaAs. Diagram 1302 show a side view of the composite wafer after 1204. Diagram 1302 includes solar cell layer 1312, metal layer 1306, and substrate layer 1304. Solar cell layer 1312 includes semiconductor layer 1308, the solar cell substrate. For example, solar cell layer 1312 could comprise the layers shown in solar cell 200 (FIG. 2B), where the semiconductor layer 1308 is Ge.

The thickness of the substrate layer is chosen to give the desired electrical isolation, thermal resistance, and structural stability to the structure. For example, approximately 250 microns of AlN may be used in some applications.

Some advantages of process 1200 include being able to use less semiconductor material since the substrate layer provides support for the structure. For example, the amount of semiconductor material needed may be reduced by a factor of ten. Because semiconductor material can be expensive, this may significantly save on costs. In addition, a semiconductor can have relatively low thermal conductivity. By lowering the amount of semiconductor material used in the solar cell, the thermal resistance from the solar cell to the heat sink and/or ambient environment is reduced and, as a result, the efficiency of the solar cell is increased. Also, having the substrate layer in intimate contact with the semiconductor layer provides excellent thermal contact, improving performance and reliability, while also eliminating a separate die attach process of the die to substrate, thereby further reducing cost. In addition, the solar cell is heat sensitive and some bonding processes require heat, which could damage the solar cell. Therefore, not having to perform a bonding process involving a solar cell can be desirable.

FIG. 14 is a flow chart illustrating an embodiment of a process for creating a pre-growth composite wafer through deposition. For example, process 1400 may be used to perform 1202. At 1402, a semiconductor wafer is obtained. The semiconductor may be Ge, GaAs, Si, or a III-V semiconductor in various embodiments. At 1404, a metal layer is applied to the semiconductor wafer. For example, the metal layer may be deposited on the semiconductor wafer. In various embodiments, the metal layer is an adhesion promoting interlayer that provides an electrical contact. At 1406, a substrate layer is deposited on to the metal layer. The substrate layer is an electrically insulating, thermally conductive material, such as a ceramic, Aluminum Nitride (AlN), diamond, Alumina (Al2O3), Si3N4, SiO2, semiconductors, such as semi-insulating silicon, or other dielectrics For example, CVD, physical vapor deposition (PVD), pulsed laser deposition, or atomic laser deposition may be used to perform 1406.

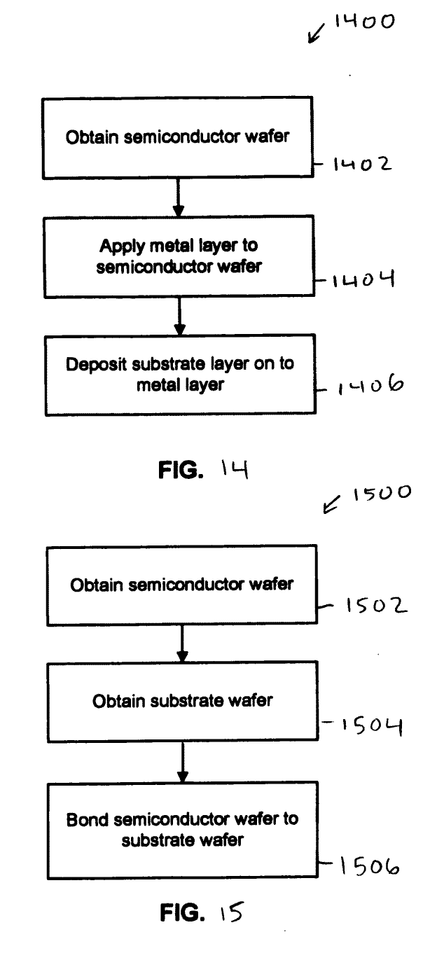

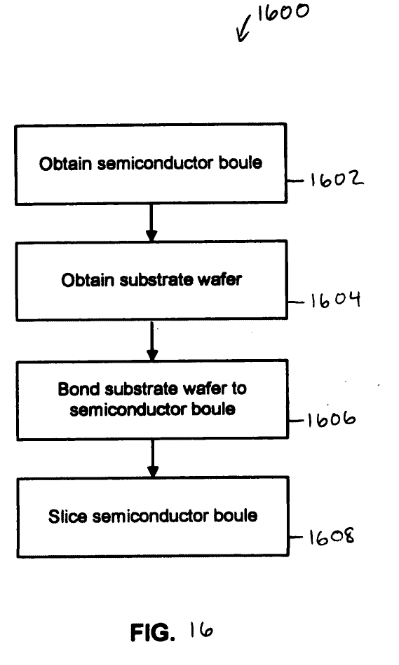

FIG. 15 is a flow chart illustrating an embodiment of a process for creating a pre-growth composite wafer through bonding. For example, process 1500 may be used to perform 1202. Process 1500 is an alternative to process 1400. At 1502, a semiconductor wafer is obtained. The semiconductor may be Ge, GaAs, Si, or a III-V semiconductor in various embodiments. At 1504, a substrate wafer is obtained. At 1506, the semiconductor wafer is bonded to the substrate wafer. For example, a wafer bonding process, solder, or an adhesive, such as a silver filled epoxy, may be used to perform 1506. The substrate wafer could be a preformed layered structure, e.g., a metal layer with an electrical insulating material, such as 2-10 microns of SiO₂ or Si₃N₄ on one side, to provide electrical isolation.

In various embodiments, one or more intermediate layers are deposited on the semiconductor and/or substrate wafer to promote bonding and/or to provide back side electrical contact. The number and type of layers are chosen to facilitate a particular wafer bond approach, promote adhesion, minimize thermal impedance, and provide an electrical back contact. The wafer bonding approach could be anodic bonding, eutectic bonding, or silicon direct bonding in various embodiments. In the post bonding wafer fabrication steps, a thin bonding layer may be removed to access the back side contact.

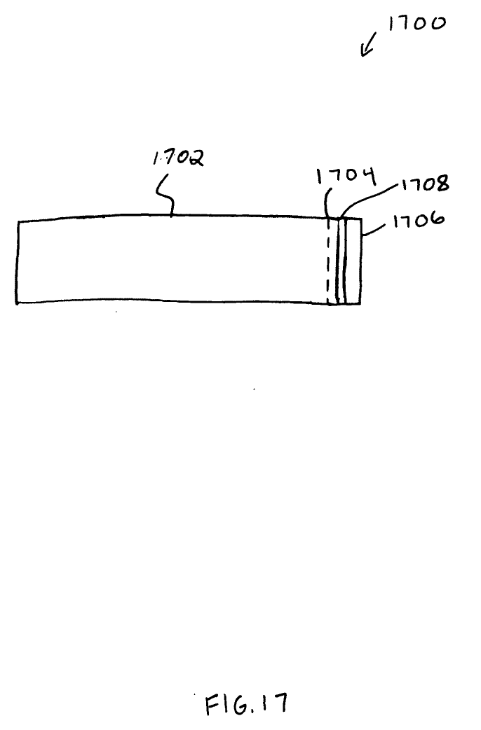

FIG. 16 is a flow chart illustrating an embodiment of a process for creating a pre-growth composite wafer from a semiconductor boule. For example, process 1600 may be used to perform 1202. Process 1600 is an alternative to processes 1400 and 1500. At 1602, a semiconductor boule is obtained. The semiconductor may be Ge, GaAs, Si, or a III-V semiconductor in various embodiments. Besides a boule, other structures of semiconductor material may be used in various embodiments. For example, an ingot, a thick wafer, or any other size and shape structure that is larger than the final desired size of the semiconductor material may be used. At 1604, a substrate wafer is obtained. At 1694, the substrate wafer is bonded to the semiconductor boule. For example, a cross sectional surface of the boule may be polished and the substrate wafer may be attached to the cross sectional surface. A wafer bonding process (as previously described), solder, or an adhesive may be used to perform the bonding. At 1608, the semiconductor boule is sliced. For example, a wire saw or wafer saw may be used. In some embodiments, the boule could be implanted with ions prior to wafer bonding to create a stress zone at a particular depth from the cross sectional surface. After wafer bonding, the semiconductor can be separated by applying a stress to the appropriate location and cleaving off a thin slice of semiconductor along with the attached substrate layer. In other words, the slice is fractured off the semiconductor boule. In some embodiments, the slice is on the order of 500 microns thick and the semiconductor layer is on the order of 160 micron or less thick. In some embodiments, the slice is less than 2000 microns thick and the semiconductor layer of the slice is less than 1000 microns thick. It is possible to have such a thin slice because the substrate provides support for the structure.

FIG. 17 is a diagram illustrating an example of a process for creating a pre-growth composite wafer from a semiconductor boule. Diagram 1700 shows a side view of a semiconductor boule 1702. Substrate wafer 1706 is attached to a cross sectional surface of semiconductor boule 1702 via metal layer 1708. The slice is taken along slice line 1704. The slice is then similar to pre-growth composite wafer in diagram 1300. The process may be repeated and as many slices as desired may be sliced off semiconductor boule 1702.

Encapsulant for Photovoltaic Device. Solar photovoltaic cells pose several challenges in their packaging. They require protection from the environment, an unobstructed view of sunlight to the cells, as well as thermal cooling and electrical insulation. These requirements pose competing attributes with existing technologies. Traditional PV panels are encapsulated in materials like glass, EVA, and tedlar. Typically, the system is housed in a box with a glass lid. While appropriate for unconcentrated PV cells, the traditional approaches typically do not satisfy the needs of concentration applications where the solar cell is much smaller, and is subject to more stringent thermal requirements and greater optical performance needs.

For concentrated solar cells, it would be desirable to provide environmental protection and electrical isolation that also allows light through. For concentrated solar cells, there are thin coatings applied to the solar cell for antireflective purposes, similar to low-E type coatings, but these do not meet the requirements for electrical and environmental isolation. There is currently no application of coatings directly to the solar cell for the purposes of electrical isolation and environmental protection. Coating solar cells and circuitry board with a transparent, index matched dielectric encapsulant is described.

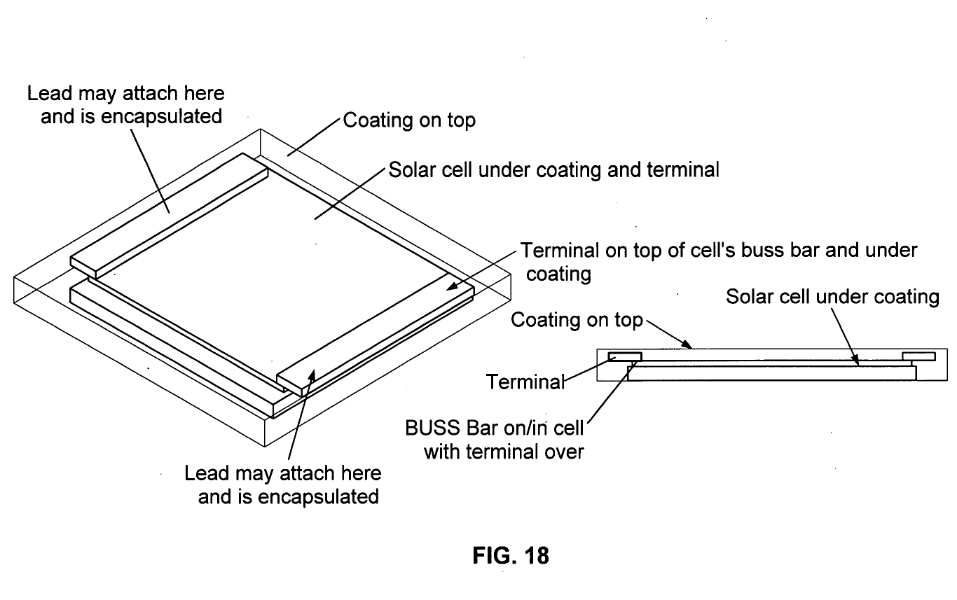

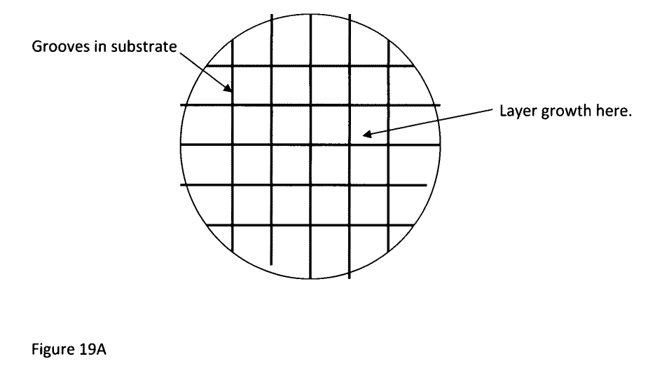

FIG. 18 is a diagram illustrating an encapsulant for a photovoltaic device. The coating protects the solar cell from ground faults and shorts such as from rain, while providing a hard and durable coating that does not significantly reduce optical performance. In some embodiments, nanomaterials are used for the coating. In some embodiments, Aluminum Oxides and Aluminum Nitrides are used. Other materials that can be used include diamond, SiO₂, or any other appropriate transparent dielectric (electrical insulator), or optically transparent and electrically insulating material. In some embodiments, a combination of two or more materials applied. In some embodiments, the coating is deposited by thin film deposition processes, such as sputtering, e-beam with ion gun, plasma chemical vapor deposition, or magnetron sputtering. This coating may also be a component layer in an anti-reflection coating system. The thickness and quality of the coating or film are selected as appropriate for the application. Quality includes how transparent and stable the material is. For example, a transparency value of 90% or greater is used in some embodiments. The coating is thick enough to provide environmental protection and electrical insulation. For example, a thickness of 3 microns is used in some embodiments. For electrical insulation, the thickness depends on the breakdown voltage required.

In some embodiments, a thick coat of a single layer of SiO2 is applied, e.g., using a spray gun or chemical vapor deposition (CVD) chamber. In some embodiments, the coating does not substantially change the optical properties of the light received at the solar cell, but blocks water and electrical charge. In some embodiments, the coating would need to be deposited at low temperature. Because low temperature can make it difficult to obtain the required quality, Pulsed Laser Deposition may be used to apply the coating.

In some embodiments, first a thin antireflective coating is applied to the solar cell. Then, the solar cell is soldered down and packaged. Then, a thicker top layer is applied. The top layer could be SiO2 or Aluminum Nitride, for example. The top layer provides environmental protection and electrical isolation. In some embodiments, the top layer is applied to the whole circuit (e.g., including the solar cell leads), and not just to the solar cell. This is to prevent water and electrical charge from getting in.

The coating acts as an encapsulant. By letting in light and sealing, electricity is isolated from flowing and environmental protection is provided (e.g., water and acid rain are blocked). In other embodiments, the coating may be applied to non-concentrated solar cells, such as flat panel solar cells on rooftops.

Some coating techniques are line of sight, in which case the coating does not reach all the areas that need to be covered. In some embodiments, the coverage can be achieved by making everything flat or sealed from the back first, and then coating the top. To get a complete seal from water or other penetration and to increase electrical isolation, the parts that are to be coated are first sealed on all sides except for the top. This allows the line of site deposition to cover the remaining exposed surface.

Diamond is a coating that may be used in some applications. For example, about 2-3 microns of material would provide 2200 Volts of standoff, as well as sealed, chemically resistant surface which has the widest optical transmission of any material. Diamond can be deposited by pulsed laser deposition while keeping the substrate at or near room temperature.

A thin solar cell. A thin solar cell with most of the substrate material removed, and that is attached to a substrate for further integration into a photovoltaic system is disclosed. By using only the thickness of solar material that actually contributes to photovoltaic (PV) current generation, the thermal impedance of the remaining semiconductor substrate, which has no purpose other than to maintain mechanical robustness to facilitate subsequent handling of the cell, is reduced. III-V semiconductors such as GaAs, have low thermal conductivity compared to metals and many ceramics. By eliminating the majority of the substrate from the cell, the thermal resistance from the junction to the ambient environment is reduced and the efficiency will be increased over what it would be with the substrate on.

The cost of a cell may be decreased by a number of features. The amount of semiconductor material needed is only that required to get full utilization of the sunlight. This reduces the amount of semiconductor needed to make the cell by over 10×, which greatly reduces the cell cost since the semiconductor material is typically the most expensive material in the cell assembly.

Another feature in some embodiments is attaching a substrate to the solar cells while it is still in wafer form. This takes advantage of batch processing typical of semiconductor fabrication to reduce fabrication steps and minimize the handling of individual parts. In doing this, cost of the solar assembly is lowered.

In some embodiments, a method of fabricating the integrated solar cell/substrate assembly is as follows:

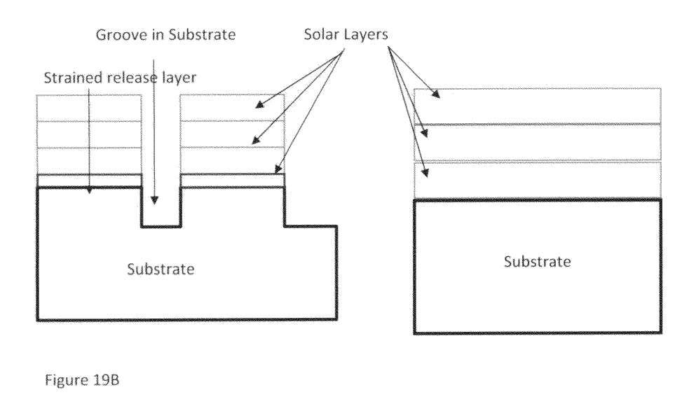

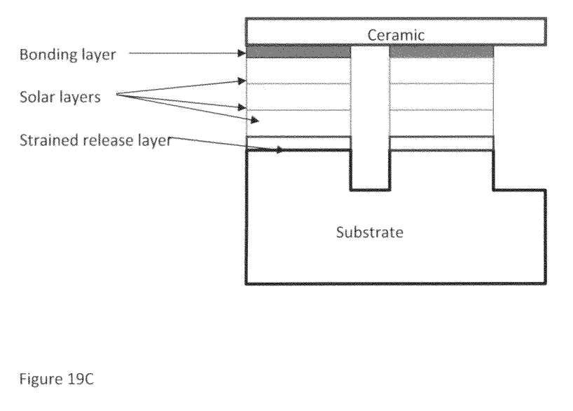

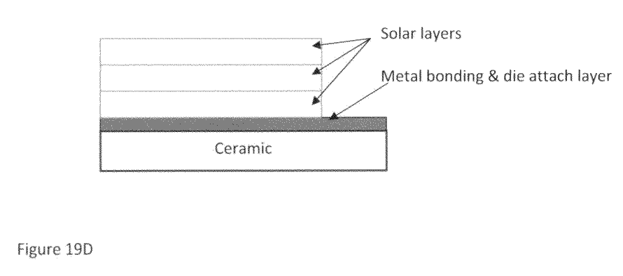

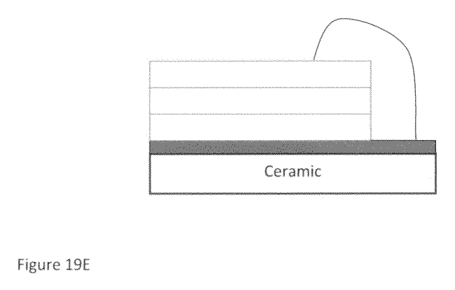

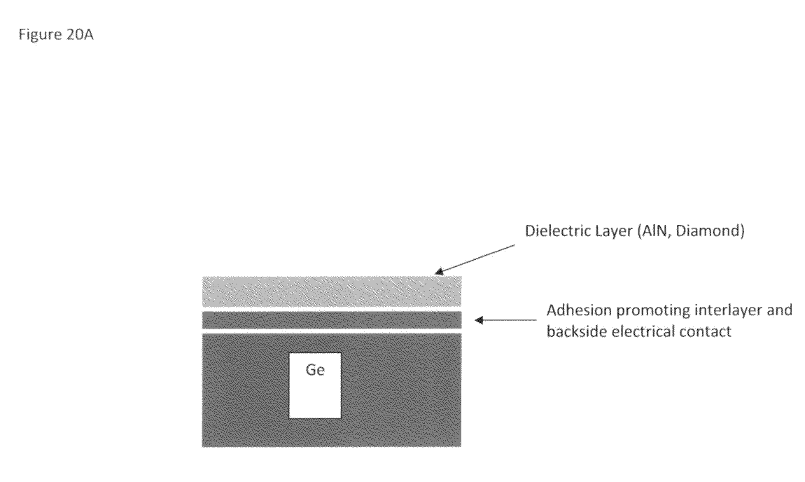

FIG. 19A is a diagram illustrating a patterned GaAs substrate ready for epitaxial growth. In some embodiments, the semiconductor substrate, for example GaAs, on which the active solar cells (the stack) will grown is grooved by sawing, laser cutting, etching or other appropriate methods. The width of the groove will be large enough to allow separation of the individual die and accommodate a bonding area on the ceramic substrate as described below. This is the substrate onto which subsequent epitaxial layers will be grown to form the solar cell.

In some embodiments, the GaAs substrate is not grooved but in normal planar form used for epitaxial deposition. Epitaxial growth begins with a sacrificial layer adjacent to the substrate, that will later be used to release the solar layers from the substrate. For example this might be layer with sufficient lattice mismatch that there is considerable strain energy built into the layer. On top of the strained layer are grown the desired solar adsorption layers.

FIG. 19B is a diagram illustrating a schematic comparison between a thin solar cell and a conventional three layer solar cell. Additional layers may be grown to for lattice matching of the solar layers or to minimize dislocation movement.

FIG. 19C is a diagram illustrating a schematic diagram of a ceramic substrate attached to a semiconductor wafer. In some embodiments, once the semiconductor material has been deposited, a substrate is attached to the top solar layer. There are a number of forms this might take. For example, onto the finished wafer a metal layer is deposited that is suitable for die attach. A metallized ceramic substrate, of approximately the same shape as the semiconductor wafer, will then be attached to the semiconductor wafer using for example low temperature solders or thermally conducting epoxy.

Another embodiment is to deposit a thin nucleation layer on the top solar layer and then deposit a diamond or ceramic layer through appropriate CVD or PVD processes.

Once the structure shown in FIG. 19C is formed the solar layers are freed from the underlying semiconductor substrate at the strained release layer. This could be done by applying a localized stress such as an impulse or thermal shock to the release layer to initiate a crack along the strain layer that releases the built in stress. Additional force could be applied to the surfaces of the ceramic and the semiconductor substrate to help release all the individual solar cells defined by the groove. Selective etches that attack preferentially the release layer could be used alone or in conjunction with other methods to facilitate release of the solar cells. The presence of the groove reduces the area that needs to be freed from the semiconductor substrate and enables the free flow etchant to access the release layer.

Once release of the solar cells from the semiconductor is completed, any remaining release layer can be removed and the ceramic or diamond substrate can be cut by laser or saw to the final size needed for mounting into a PV assembly. The grove is large enough to allow a wire bond area on the ceramic so the top layers of the cells can be wire bonded to the appropriate pad on the ceramic.

In the case where no grooves are made in the starting material, subsequent masking and etching can be done to remove some of the solar layers and define bonding pads on the ceramic.

FIG. 19D is a diagram illustrating a schematic of an individual solar cell after release. Shown in FIG. 19D is the solar cell on ceramic substrate after separation in the case starting with the grooved substrates and in the ungrooved case after subsequent patterning and etching. In both approaches, all etching steps are completed in full wafer form with the ceramic acting as the mechanical structure with sufficient strength to allow handling in wafer form.

The GaAs substrate can now be repolished and reused for additional solar cell growth, helping again to lower the cost of the solar cell.

Once the die are individually freed, the wire bonds can be made to the pad on the ceramic. FIG. 19E is a diagram illustrating a solar cell on a ceramic substrate with wire bonds. The PV cell is then ready to be inserted into a PV system.

Reducing cost and improving performance of a high performance single crystal solar cell. A method for reducing cost and improving performance of a high performance single crystal solar cells, such as GaAs cells or triple junction cells such as InGaP/GaAs/Ge, is disclosed. In some embodiments the goal is to deposit a suitable dielectric material such as AlN or diamond directly onto the solar cell material while in wafer form. The dielectric would provide structural support for the subsequent deposition and wafer fabrication of the solar material. It would also minimize the use of expensive material such as Ge. With properly chosen materials the thermal resistance from cell to the ambient environment can be minimized compared to conventional cell assemblies, especially in concentrating photovoltaic applications.

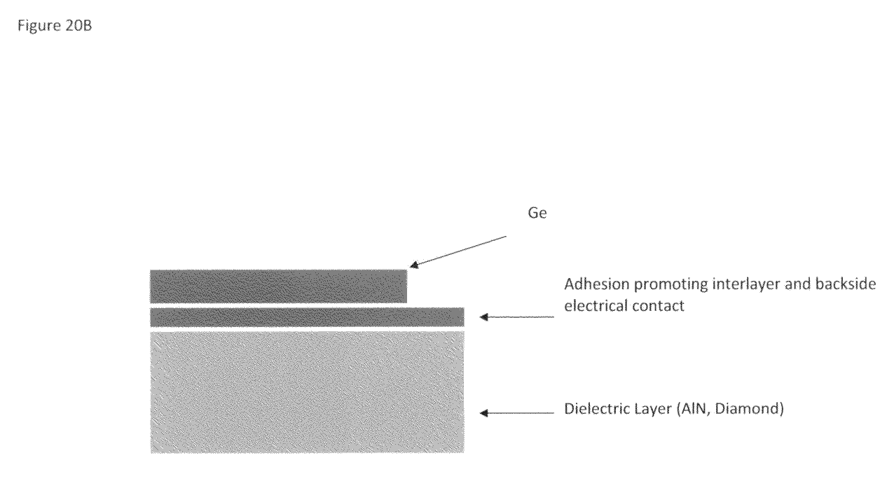

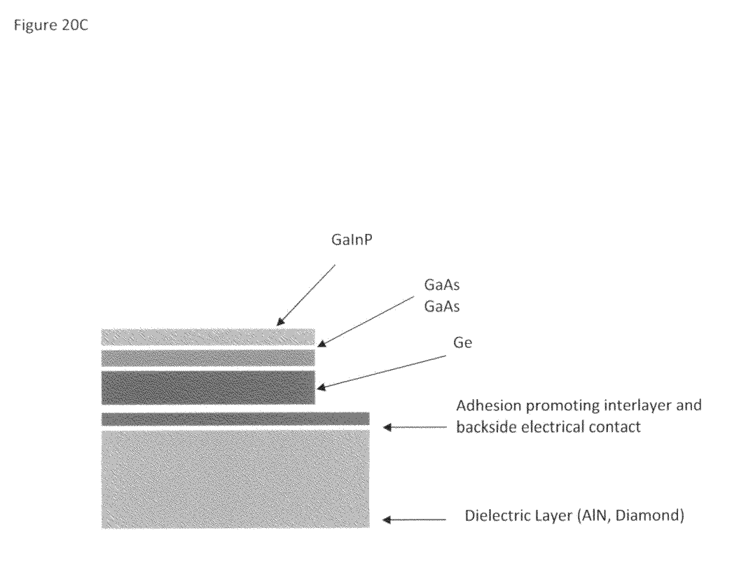

FIG. 20A is a diagram illustrating a schematic diagram of adhesion with a crystal. In some embodiments, one starts with a thick Ge substrate wafer of crystal boule before sawing into wafer form, deposit on the surface of the Ge a layer of dielectric material, such as AlN, diamond, or SiO2. The thickness of the dielectric material is chosen to give the desired electrical isolation, thermal resistance and structural stability to the finished structure. For example, approximately 250 microns of AlN may be adequate. An metal layer that acts as an adhesion promoting interlayer and electrical contact is applied to the Ge prior to deposition of the dielectric layer. The dielectric can be deposited by a number of methods such as CVD, pulsed laser deposition, or atomic layer deposition.

FIG. 20B is a diagram illustrating a schematic diagram of etched adhesion. Once the layers are deposited on the thick Ge wafer or Ge crystal boule, the dielectric layer along with a thin layer of Ge, typically 3-10 microns thick) is separated from the thick wafer or boule by one of a variety of techniques such that a wafer type assembly that would be suitable for standard epitaxial growth and subsequent wafer fabrication into solar cells. Polishing of the Ge surface may be needed prior to epi growth. In order to access the back side contact, a small section of Ge is removed using standard lithography and etch techniques to define and etch back to the interlayer.

The Ge can be separated by a variety of methods, for example wafer sawing. Ion implantation into the thick Ge or crystal boule prior to deposition of the dielectric layer can create a stress zone at a precise depth from the surface. After depositing the dielectric, the Ge can be separated by applying a stress to the appropriate location and cleaving off a thin layer of Ge along with the attached dielectric resulting in the structure shown in FIG. 20B.

FIG. 20C is a diagram illustrating a schematic diagram of subsequent epitaxial growth. Once the Ge surface is prepared for subsequent epitaxial growth, the remaining layers necessary for a triple junction (or multiple layer junction) can be done such as shown in FIG. 20C. Not shown in the figure are the tunnel junction and grading layers that are part of a standard multiple junction solar cell. It can then be processed in standard MOCVD systems for epitaxial growth and subsequent wafer fabrication steps using conventional equipment.

An advantage is less expensive Ge is used since the thick starting Ge wafer or boule can be reused. Having the dielectric layer in intimate contact with the semiconductor layer provides excellent thermal contact without the need of a standard die attach of die to substrate. The cost is further reduced by the elimination of the die attach step.

A wafer bonding method for reducing cost and improving performance of a high performance single crystal solar cell cells such as GaAs cells or triple junction cells such as InGaP/GaAs/Ge is disclosed. In some embodiments, a goal is to attach a support wafer with high electrical isolation an high thermal conductivity directly onto the solar cell material while in wafer form. The support wafer would provide structural strength for the subsequent deposition and wafer fabrication of the solar material, while providing the necessary electrical isolation and high thermal conductivity needed for optimal solar cell performance. It would also minimize the use of expensive material such as Ge. With properly chosen materials the thermal resistance from cell to the ambient environment can be minimized compared to conventional cell assemblies, especially in concentrating photovoltaic applications.

In some embodiments, one starts with a thick Ge substrate wafer of crystal boule before sawing into wafer form, A layer of dielectric material, such as AlN, diamond, Al2O3, or a semi-insulating Si wafer is attached to the Ge using a wafer bonding technique. The support layer itself could be a preformed layered structure, for example a metal layer with an electrical insulating material, such as 2-10 microns of SiO2 or Si3N4 on one side, to provide the necessary electrical isolation.

In some embodiments, one or more intermediate layers are deposited on either the Ge, the support wafer or both to promote bonding and to provide backside electrical contact. These layers may be insulating or a conducting. The number and type of layers are chosen to facilitate a particular wafer bond approach, promote adhesion, minimize thermal impedance, and provide an electrical back contact. The wafer bonding approach could be anodic bonding, eutectic bonding, or silicon direct bonding. It will be known to those skilled in the art that in the post bonding wafer fabrication steps, a thin bonding layer may be removed to access the backside contact.

In some embodiments, the thickness of the support material is chosen to give the desired electrical isolation, thermal resistance and structural stability to the finished structure. For example, approximately 250 microns of AlN may be adequate. An example of this structure is shown in FIG. 20A.

Once the layers are deposited on the thick Ge wafer or Ge crystal boule, the dielectric layer along with a thin layer of Ge, typically 3-10 microns thick) is separated from the thick wafer or boule by one of a variety of techniques such that a wafer type assembly that would be suitable for standard epitaxial growth and subsequent wafer fabrication into solar cells. Polishing of the Ge surface may be needed prior to epi growth. In order to access the back side contact, a small section of Ge is removed using standard lithography and etch techniques to define and etch back to the interlayer. FIG. 20B is an example schematic of this structure.

In some embodiments, the Ge can be separated by a variety of methods, for example wafer sawing. Ion implantation into the thick Ge or crystal boule prior to wafer bonding can create a stress zone at a precise depth from the surface. After wafer bonding, the Ge can be separated by applying a stress to the appropriate location and cleaving off a thin layer of Ge along with the attached support layer resulting in the structure shown in FIG. 20B.

Once the Ge surface is prepared for subsequent epitaxial growth, the remaining layers necessary for a triple junction (or multiple layer junction) can be done such as shown in FIG. 20C. Not shown in the figure are the tunnel junction and grading layers that are part of a standard multiple junction solar cell. The cell can then be processed in standard MOCVD systems for epitaxial growth and subsequent wafer fabrication steps using conventional equipment.

One key advantage is less expensive Ge is used since the thick starting Ge wafer or boule can be reused. Having the support layer in intimate contact with the semiconductor layer provides excellent thermal contact without the need of a standard die attach of die to substrate. The cost is further reduced by the elimination of the die attach step.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A solar cell package, comprising:
an electrically insulating and thermally conductive first layer;
an electrically conductive second layer attached to the first layer; and
a solar cell attached to the second layer, wherein a first layer surface and a solar cell surface have substantially the same surface area.

2. A solar cell package as recited in claim 1, wherein the first layer surface is the surface of the first layer that is in contact with the second layer.

3. A solar cell package as recited in claim 1, wherein the solar cell surface is the surface of the solar cell that is in contact with the second layer.

4. A solar cell package as recited in claim 1, wherein the solar cell surface is the bottom surface of the solar cell.

5. A solar cell package as recited in claim 1, wherein the first layer surface is the top surface of the solar cell.

6. A solar cell package as recited in claim 1, wherein at least one edge of the solar cell is substantially aligned with at least one edge of the first layer.

7. A solar cell package as recited in claim 1, wherein the second layer is metal.

8. A solar cell package as recited in claim 1, wherein at least one edge of the solar cell is mutually aligned with at least one edge of the first layer.

9. A solar cell package as recited in claim 1, further including at least one ledge between at least one edge of the first layer and at least one edge of the solar cell.

10. A solar cell package as recited in claim 1, wherein at least one edge of the first layer extends beyond at least one edge of the solar cell to create at least one underhanging ledge.

11. A solar cell package as recited in claim 1, wherein at least one edge of the solar cell extends beyond at least one edge of the first layer to create at least one overhanging ledge.

12. A solar cell package as recited in claim 9, wherein the at least one ledge has a ledge width that is <2 millimeters.

13. A solar cell package as recited in claim 9, further including a bonding wire attached to the at least one ledge.

14. A solar cell package as recited in claim 13, wherein the bonding wire is a positive terminal.

15. A solar cell package as recited in claim 9, further including a perimeter contact attached to the at least one ledge.

16. A solar cell package as recited in claim 9, further including a ribbon bond or leadframe interconnect attached to the at least one ledge.

17. A solar cell package as recited in claim 1, wherein each edge of the solar cell is substantially aligned with each edge of the first layer.

18. A solar cell package as recited in claim 1, wherein the first layer is a ceramic, Aluminum Nitride (AlN), diamond, Alumina (Al₂O₃), Si₃N₄, SiO₂, a semiconductor, a semi-insulating silicon, or a dielectric.

19. A solar cell package as recited in claim 1, wherein the first layer and the solar cell are joined using an epoxy or solder.

20. A solar cell package as recited in claim 1, wherein the solar cell package is cut from a composite wafer.

21. A solar cell package as recited in claim 1, wherein the first layer and the solar cell are joined using a wafer bonding process.

22. A solar cell package as recited in claim 1, wherein the solar cell includes at least one layer that is grown on a semiconductor layer after the semiconductor layer is bonded to the first layer.

23. A solar cell package as recited in claim 22, wherein the second layer is applied to the semiconductor layer.

24. A solar cell package as recited in claim 1, wherein the first layer is deposited on the second layer.

25. A solar cell package as recited in claim 22, wherein the semiconductor layer is bonded to the first layer.

26. A solar cell package as recited in claim 22, wherein the semiconductor layer is sliced from a semiconductor boule onto which the first layer was bonded.

27. A solar cell package as recited in claim 26, wherein a slice is less than 2000 microns thick.

28. A solar cell package as recited in claim 1, further including a protective coating applied to the solar cell.

29. A method of creating a solar cell package, comprising:
obtaining an individual solar cell;
obtaining an individual electrically insulating and thermally conductive substrate; and
bonding the individual solar cell to the individual substrate wherein a substrate surface and a solar cell surface have substantially the same surface area.

30. A method as recited in claim 29, wherein the bonding is via an electrically conductive material.

31. A method as recited in claim 29, wherein the substrate is a ceramic, Aluminum Nitride (AlN), diamond, Alumina (Al₂O₃), Si₃N₄, SiO₂ or semiconductor, a semi-insulating silicon, or a dielectric.

32. A method of creating a solar cell package, comprising:
creating a composite wafer comprising a solar cell layer bonded to an electrically insulating and thermally conductive substrate layer;
defining a plurality of individual solar cells and an associated individual substrate for each solar cell on the composite wafer, wherein a surface of each solar cell and a surface of its associated individual substrate have substantially the same surface area;
etching the composite wafer through the solar cell layer to a metal layer in between the solar cell layer and the substrate layer; and
cutting through the metal layer and the substrate layer to create a plurality of solar cell packages.

33. A method as recited in claim 32, wherein creating a composite wafer includes coating each of a solar cell wafer and a substrate wafer with metal.

34. A method as recited in claim 33, wherein creating a composite wafer further includes bonding the solar cell wafer and the substrate wafer at the metal layers.

35. A method as recited in claim 32, wherein creating a composite wafer includes creating a pre-growth composite wafer comprising a semiconductor layer bonded to the substrate layer via a metal layer.

36. A method as recited in claim 35, wherein creating a composite wafer further includes growing at least one layer of the solar cell layer on the semiconductor layer.

37. A method as recited in claim 35, wherein the semiconductor layer is Ge, GaAs, Si, or a III-V semiconductor.

38. A method as recited in claim 35, wherein creating the pre-growth composite wafer includes depositing a metal layer and the substrate layer on to a semiconductor wafer.

39. A method as recited in claim 35, wherein creating the pre-growth composite wafer includes bonding a semiconductor wafer to a substrate wafer via a metal layer.

40. A method as recited in claim 35, wherein creating the pre-growth composite wafer further includes bonding a substrate wafer to a semiconductor boule.

41. A method as recited in claim 40, wherein creating the pre-growth composite wafer further includes slicing the semiconductor boule.

42. A method as recited in claim 40, wherein a slice is less than 2000 microns thick.

43. A method as recited in claim 40, wherein slicing includes using a wire saw.

44. A method as recited in claim 40, wherein slicing includes implanting the semiconductor boule with ions and fracturing the semiconductor boule.
